(19) United States
(12) Patent Application Publication
(10) Pub. No.: US 2009/0295421 A1
(43) Pub. Date: Dec. 3, 2009

(54) TEST PATTERN OF SEMICONDUCTOR DEVICE, METHOD OF MANUFACTURING THE SAME, AND METHOD OF TESTING DEVICE USING TEST PATTERN

(76) Inventor: Dae-Kyeun Kim, Yongin-si (KR)

Correspondence Address: SHERR & VAUGHN, PLLC, 620 HERNDON PARKWAY, SUITE 320, HERNDON, VA, 20170, US

(21) Appl. No.: 12/473,348

(22) Filed: May 28, 2009

(30) Foreign Application Priority Data
May 30, 2008 (KR) 10-2008-0050823

(51) Int. Cl. G01R 31/26; H01L 23/544; H01L 21/3205

(52) U.S. Cl. 324/765; 257/48; 438/761; 257/E23.179; 257/E21.295

(57) ABSTRACT

Disclosed are a test pattern of a semiconductor device, a method of manufacturing the same, and a method of testing the device using the test pattern. The test pattern includes a lower metal pattern part formed over a semiconductor substrate, an intermetal insulating film formed over the lower metal pattern part, and upper metal pattern test parts formed over the intermetal insulating film such that the upper metal pattern parts are separated from each other by a designated distance.

The present application claims priority under 35 U.S.C. 119 to Korean Patent Application No. 10-2008-0050823 (filed on May 30, 2008), which is hereby incorporated by reference in its entirety.

### BACKGROUND

In the manufacture of a semiconductor device using copper lines, metal lines may be formed by a damascene process. Hereinafter, a method of manufacturing a semiconductor device by the damascene process will be described with reference to the accompanying drawings. FIGS. 1 to 4 are longitudinal-sectional views illustrating a general method of manufacturing metal lines by the damascene process, and FIG. 5 is a plan view of a metal film 40 of FIG. 4.

With reference to FIG. 1, trenches to form metal lines are formed by patterning an insulating film 10 by photolithography. With reference to FIG. 2, a metal layer is stacked over the insulating film 10 to fill the trenches of the insulating film 10, and is polished by chemical mechanical polishing (CMP) until the upper surface of the insulating film 10 is exposed. For example, the metal layer may be made of copper (Cu), aluminum (Al), or tungsten (W).

By the above method, metal lines 22, 24, and 26 may be formed in the insulating film 10. As the widths of the metal lines 22, 24, and 26 are increased, dishing, where a specific portion is deeply hollowed in a dish shape, is markedly generated.

As shown in FIG. 2, the metal line 24 having a larger width exhibits dishing, compared with the metal lines 22 and 26 having a smaller width. That is, the depth of the dishing is directly proportional to the size of the pattern.

With reference to FIG. 3, an intermetal dielectric film 30 is stacked over the upper surface of the insulating film 10 including the metal lines 22, 24, and 26. In this case, the upper surface of the intermetal dielectric film 30 stacked over the upper surface of the metal line 24 has a dishing profile 34 due to the dishing profile of the metal line 24.

With reference to FIG. 4, metal lines 42, 44, and 46 are formed in the upper surface of an intermetal insulating film 32 by the damascene process, as described above, with the intermetal insulating film 32 stacked over the upper surface of insulating film 12. In this case, a metal film 40 is unnecessarily formed in a depression formed on the upper surface of the intermetal insulating film 30 by the dishing profile 34.

If the unnecessary metal film 40 is formed, as shown in FIGS. 4 and 5, the unnecessary metal film 40 influences the copper metal line passing around the metal film 40, and thus causes bridges due to shorts between the wire lines.

In this case, a defective chip may be detected through yield inspection. However, the yield inspection is a process of testing manufactured chips, and thus continuously incurs an additional test cost.

### SUMMARY

Embodiments relate to a semiconductor device, and more particularly, to a test pattern of a semiconductor device, a method of manufacturing the same, and a method of testing the device using the test pattern. Embodiments relate to a test pattern of a semiconductor device, which allows a defect of the semiconductor device caused by dishing to be detected by electrical inspection prior to yield inspection, and a method of manufacturing the test pattern. Embodiments relate to a method of testing a semiconductor device, in which a defect of the semiconductor device caused by dishing is detected by electrical inspection using the test pattern prior to yield inspection.

Embodiments relate to a test pattern of a semiconductor device which includes a lower metal pattern part formed over a semiconductor substrate, an intermetal insulating film formed over the lower metal pattern part, and upper metal pattern test parts formed over the intermetal insulating film such that the upper metal pattern parts are separated from each other by a designated distance.

Embodiments relate to a method of manufacturing a test pattern of a semiconductor device which includes forming a lower metal pattern part over a semiconductor substrate, forming an intermetal insulating film over the lower metal pattern part, and forming upper metal pattern test parts formed over the intermetal insulating film such that the upper metal pattern parts are separated from each other by a designated distance and are opposite to each other.

Embodiments relate to a method of testing a semiconductor device using a test pattern, having a lower metal pattern part formed over a semiconductor substrate by planarization, an intermetal insulating film formed over the lower metal pattern part, and upper metal pattern test parts formed over the intermetal insulating film such that the upper metal pattern parts are separated from each other by a designated distance, which includes applying test current to a first one of the upper metal pattern test parts, measuring current flowing out of a second one of the upper metal pattern test parts, and determining whether or not the semiconductor device is defective using the test current and the measured current.

### DRAWINGS

FIGS. 1 to 4 are longitudinal-sectional views illustrating a method of manufacturing metal lines by a damascene process.

FIG. 5 is a plan view of a metal film of FIG. 4.

Example FIG. 6 is a plan view of a test pattern of a semiconductor device in accordance with embodiments.

Example FIG. 7 is a longitudinal-sectional view taken along the line A-A′ of example FIG. 6.

Example FIG. 8 is a plan view of a test pattern of a semiconductor device in accordance with embodiments.

### DESCRIPTION

Hereinafter, a test pattern of a semiconductor device in accordance with embodiments will be described in detail with reference to the accompanying drawings. Example FIG. 6 is a plan view of a test pattern of a semiconductor device in accordance with embodiments, and example FIG. 7 is a longitudinal-sectional view taken along the line A-A′ of example FIG. 6.

With reference to example FIGS. 6 and 7, the test pattern includes lower metal pattern parts 100, 102, and 104, an intermetal insulating film 130, and upper metal pattern parts 110 and 112. The lower metal pattern parts 100, 102, and 104 are formed over a semiconductor substrate by planarization. The intermetal insulating film 130 is formed over the lower metal pattern parts 100, 102, and 104, and an insulating film 10. The upper metal pattern parts 110 and 112 are formed over the upper surface of the intermetal insulating film 130 such that the upper metal pattern parts 110 and 112 are separated from each other by a designated distance. The upper metal pattern parts 110 and 112 may be formed over the upper surface of the lower metal pattern part 100 having a larger width rather than the upper surfaces of the lower metal pattern parts 102 and 104 having a smaller width. This is because the lower metal pattern part 100 has a larger width and a higher possibility of generating dishing.

In accordance with embodiments, each of the upper metal pattern parts 110 and 112 may be formed in a T shape such that the upper metal pattern parts 110 and 112 are separated from each other, as shown in example FIG. 6. The upper metal pattern parts 110 and 112 and the lower metal pattern parts 100, 102, and 104 may be made of one selected from the group consisting of pure metals including aluminum (Al), tungsten (W), molybdenum (Mo), cobalt (Co), titanium (Ti), copper (Cu), and platinum (Pt), silicide compounds thereof, and alloys thereof.

Example FIG. 8 is a plan view of a test pattern of a semiconductor device in accordance with embodiments. In accordance with embodiments, each of upper metal pattern parts 210 and 212 may be formed in a hair comb shape such that the upper metal pattern parts 210 and 212 are separated from each other by a designated distance and are engaged with each other.

In accordance with embodiments, at least one of the upper metal pattern parts 110 and 112 or 210 and 212 and the lower metal pattern part 100 or 200 may be located on a scribe line between one chip and another chip. Further, if the test pattern, as shown in example FIG. 6 or 7, is used to test a defect in a main chip, at least one of the upper metal pattern parts 110 and 112 or 210 and 212 and the lower metal pattern part 100 or 200 may be located on the main chip. That is, the upper metal pattern parts 110 and 112 or 210 and 212 and the lower metal pattern part 100 or 200 may be located on the main chip, or only the upper metal pattern parts 110 and 112 or 210 and 212 may be located on the main chip.

The test pattern in accordance with embodiments is not limited to the shapes, as shown in example FIGS. 6 to 8, and may have various shapes. That is, the upper metal pattern parts of the test pattern may have various shapes in addition to the T-shape or the hair comb shape, as shown in example FIG. 6 or 8, so long as the upper metal pattern parts are opposite to each other and are separated from each other.

The upper metal pattern parts 210 and 212 and the lower metal pattern part 200 may be made of one selected from the group consisting of pure metals including aluminum (Al), tungsten (W), molybdenum (Mo), cobalt (Co), titanium (Ti), copper (Cu), and platinum (Pt), silicide compounds thereof, and alloys thereof.

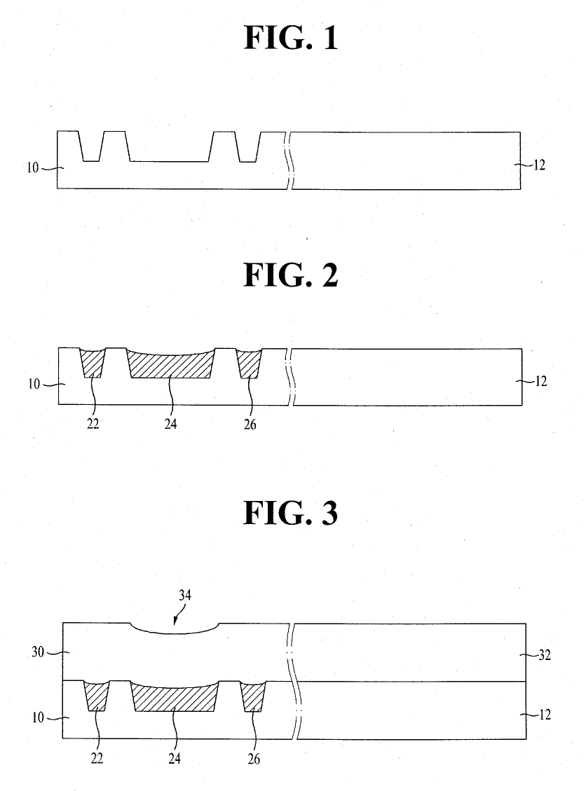

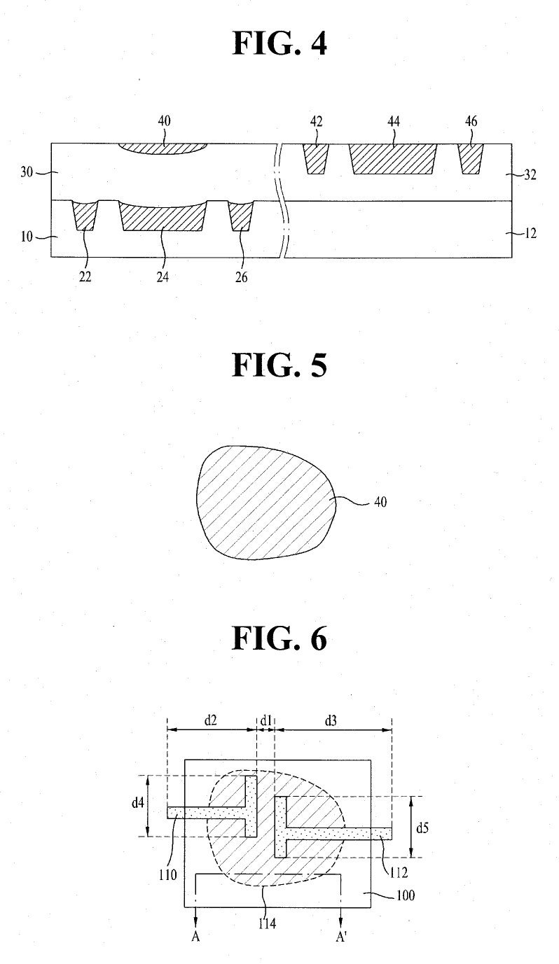

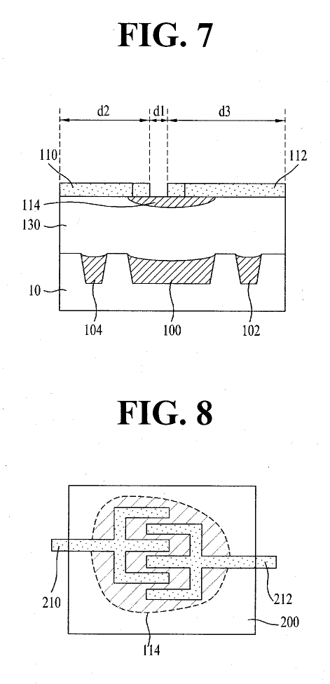

Hereinafter, a method of manufacturing a test pattern of a semiconductor device in accordance with embodiments will be described with reference to example FIGS. 6 to 8. With reference to example FIG. 7, the insulating film 10 may be formed over a semiconductor substrate. The lower metal pattern part(s) 100, 102, and 104 or 200 may be formed in the insulating film 10 by the damascene process. For example, the lower metal pattern part(s) 100, 102, and 104 or 200 may be formed by the damascene process, as shown in FIGS. 1 to 4. Thereafter, the intermetal insulating film 130 may be formed over the insulating film 10 including the lower metal pattern part(s) 100, 102, and 104 or 200 by deposition.

The upper metal pattern parts 110 and 112 or 210 and 212 may be formed over the upper surface of the intermetal insulating film 130. The upper metal pattern parts 110 and 112 or 210 and 212 may be separated from each other by a designated distance, opposite to each other. That is, each of the upper metal pattern parts 110 and 112 or 210 and 212 may be formed in a T shape, as shown in example FIG. 6, or in a hair comb shape, as shown in example FIG. 8, such that the upper metal pattern parts 110 and 112 or 210 and 212 are opposite to each other.

At least one of the distance d1 between the upper metal pattern parts 110 and 112 or 210 and 212 and the lengths d2 to d5 of respective lines of the upper metal pattern parts 110 and 112 or 210 and 212 is predetermined. Further, the predetermined distance d1 between the upper metal pattern parts 110 and 112 or 210 and 212 and the lengths d2 to d5 of the respective lines of the upper metal pattern parts 110 and 112 or 210 and 212 may be adjusted during a process. In the same manner, the horizontal and vertical lengths of each of the lower metal pattern parts 100, 102, and 104 or the lower metal pattern part 200 may be predetermined, or may be adjusted during the process.

In accordance with embodiments, at least one of the lower metal pattern part 100 or 200 and the upper metal pattern parts 110 and 112 or 210 and 212, as shown in example FIGS. 6 to 8, may be formed simultaneously with the formation of metal lines of the semiconductor device. Therefore, a separate mask process or etching process to form the lower metal pattern part 100 or 200 and the upper metal pattern parts 110 and 112 or 210 and 212 of the test pattern is not necessary.

Hereinafter, a method of testing a semiconductor device using the test pattern in accordance with embodiments will be described with reference to example FIGS. 6 to 8. In the semiconductor device in accordance with embodiments, as the widths of metal lines are increased, dishing is more easily generated due to a property of the polishing process, in which the polishing speed of a metal layer is higher than the polishing speed of an insulating layer, as described above with reference to FIGS. 1 to 4.

In this case, the unnecessary metal film 114 may be formed in a depression formed on the upper surface of the intermetal insulating film 130 by dishing. To detect a defective semiconductor device having the metal film 114, a semiconductor device is tested as follows.

First, test current may be supplied to one of the upper metal pattern parts 110 and 112 or 210 and 212. For example, the test current may flow into the left end of the upper metal pattern part 112 or 212. Thereafter, current flowing out of the other one of the upper metal pattern parts 110 and 112 or 210 and 212 may be measured. For example, the current flowing from the right end of the upper metal pattern part 110 or 210 may be measured.

Thereafter, defective semiconductor devices are detected using the test current and the measured current. If the unnecessary metal film 114 is present, when the test current flows into the upper metal pattern part 112 or 212, current from the other upper metal pattern part 110 or 210 is measured. When current from the other upper metal pattern part 110 or 210 is measured, as such, it is determined that the unnecessary metal film 114 has been formed, and thus it is determined that the semiconductor device is defective.

However, if the unnecessary metal film 114 is not present, when the test current flows into the upper metal pattern part 112 or 212, current from the other upper metal pattern part 110 or 210 is not measured. When current from the other upper metal pattern part 110 or 210 is not measured, as such, it is determined that the unnecessary metal film 114 is not formed, and thus it is determined that the semiconductor device is good. Accordingly, with the testing method in accordance with embodiments, a defect of a semiconductor device caused by dishing is electrically inspected prior to yield inspection.

As described above, in a test pattern of a semiconductor device, a method of manufacturing the same, and a method of testing the device using the test pattern in accordance with embodiments, a defect of the semiconductor device caused by dishing is filtered out by electrical inspection other than yield inspection, and thus an additional cost required in the yield inspection is reduced.

Since the defect of the semiconductor device caused by dishing is filtered out prior to the yield inspection, the defective semiconductor device is rapidly detected and a disorder in fabrication (FAB) is rapidly monitored, and thus controllability in fabrication (FAB) is improved. Since the test pattern is formed simultaneously with the formation of metal lines, a separate mask or an addition process to form the test pattern is not required and the size of a chip is not increased, and thus the application of the test pattern is easy.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A test pattern of a semiconductor device comprising:
a lower metal pattern part formed over a semiconductor substrate;
an intermetal insulating film formed over the lower metal pattern part; and
upper metal pattern test parts formed over the intermetal insulating film such that the upper metal pattern parts are separated from each other by a designated distance.

2. The test pattern according to claim 1, wherein the upper metal pattern test parts are formed in T shapes opposite to each other.

3. The test pattern according to claim 1, wherein the upper metal pattern test parts are formed in a hair comb shape engaged with each other.

4. The test pattern according to claim 1, wherein at least one of the upper metal pattern test parts and the lower metal pattern part is located on a scribe line.

5. The test pattern according to claim 1, wherein at least one of the upper metal pattern test parts and the lower metal pattern part formed as a test pattern to test a defect of a main chip is located in the main chip.

6. The method according to claim 1, wherein the upper metal pattern test parts are made of one selected from the group consisting of pure metals including aluminum (Al), tungsten (W), molybdenum (Mo), cobalt (Co), titanium (Ti), copper (Cu), and platinum (Pt), silicide compounds thereof, and alloys thereof.

7. The method according to claim 1, wherein the lower metal pattern part is made of one selected from the group consisting of pure metals including aluminum (Al), tungsten (W), molybdenum (Mo), cobalt (Co), titanium (Ti), copper (Cu), and platinum (Pt), silicide compounds thereof, and alloys thereof.

8. A method of manufacturing a test pattern of a semiconductor device comprising:
forming a lower metal pattern part over a semiconductor substrate;
forming an intermetal insulating film over the lower metal pattern part; and
forming upper metal pattern test parts formed over the intermetal insulating film such that the upper metal pattern parts are separated from each other by a designated distance and are opposite to each other.

9. The method according to claim 8, wherein the distance between the upper metal pattern parts is predetermined.

10. The method according to claim 8, wherein the lengths of respective lines of the upper metal pattern parts is predetermined.

11. The method according to claim 8, wherein the distance between the upper metal pattern parts is adjustable.

12. The method according to claim 8, wherein the lengths of respective lines of the upper metal pattern parts is adjustable.

13. The method according to claim 8, wherein the upper metal pattern test parts are formed simultaneously with the formation of other metal lines.

14. The method according to claim 8, wherein the lower metal pattern part is formed using a damascene process.

15. The method according to claim 8, wherein metal lines are formed in the intermetal insulating film using a damascene process.

16. The method according to claim 8, wherein the upper metal pattern test parts are made of one selected from the group consisting of pure metals including aluminum (Al), tungsten (W), molybdenum (Mo), cobalt (Co), titanium (Ti), copper (Cu), and platinum (Pt), silicide compounds thereof, and alloys thereof.

17. The method according to claim 8, wherein the lower metal pattern part is made of one selected from the group consisting of pure metals including aluminum (Al), tungsten (W), molybdenum (Mo), cobalt (Co), titanium (Ti), copper (Cu), and platinum (Pt), silicide compounds thereof, and alloys thereof.

18. A method of testing a semiconductor device using a test pattern, having a lower metal pattern part formed over a semiconductor substrate by planarization, an intermetal insulating film formed over the lower metal pattern part, and upper metal pattern test parts formed over the intermetal insulating film such that the upper metal pattern test parts are separated from each other by a designated distance, comprising:
applying test current to a first of the upper metal pattern test parts;
measuring current flowing out of a second of the upper metal pattern test parts; and
determining whether the semiconductor device is defective using the test current and the measured current.

19. The method according to claim 18, wherein the semiconductor device is determined to be defective when substantial current is measured flowing out of the second of the upper metal pattern parts when the test current is applied to the first of the upper metal pattern test parts.

20. The method according to claim 18, wherein the semiconductor device is determined to be good when no substantial current is measured flowing out of the second of the upper metal pattern parts when the test current is applied to the first of the upper metal pattern test parts.
